(19) United States
(12) Patent Application Publication
(10) Pub. No.: US 2021/0233796 A1
(43) Pub. Date: Jul. 29, 2021

(54) ROBOT SYSTEM

(71) Applicant: KAWASAKI JUKOGYO KABUSHIKI KAISHA, Kobe-shi, Hyogo (JP)

(72) Inventors: Takeshi SHIBATA, Akashi-shi (JP); Yuya MUROI, Himeji-shi (JP)

(73) Assignee: KAWASAKI JUKOGYO KABUSHIKI KAISHA, Kobe-shi, Hyogo (JP)

(21) Appl. No.: 17/059,492

(22) PCT Filed: May 28, 2019
(86) PCT No.: PCT/JP2019/021064

§ 371 Date: Nov. 30, 2020

(30) Foreign Application Priority Data
May 29, 2018 (JP) 2018-102160

(51) Int. Cl. H01L 21/687; H01L 21/677; B65G 47/90

(52) U.S. Cl. CPC H01L 21/68707; B65G 47/90; H01L 21/67766

(57) ABSTRACT

A robot system includes a first and second placing part where a workpiece is placed, and a transfer device disposed between the first and second placing part, the transfer device including a transfer-device interior space, a part of the periphery thereof being defined by a first wall provided to the first placing part side and a second wall provided to the second placing part side so as to oppose to the first wall, and a robot configured to transfer the workpiece between the first placing part and the second placing part. The first placing part is separated from the first wall by a first distance in a first direction connecting the first wall and the second wall. The second placing part is separated from the second wall by a second distance farther than the first distance in the first direction, and the robot is disposed closer to the second wall.

### TECHNICAL FIELD

The present disclosure relates to a robot system.

### BACKGROUND ART

Conventionally, robot systems are known. One of known robot systems is a substrate transfer system, such as the one proposed in JP2013-198981A (Patent Document 1).

The substrate transfer system of Patent Document 1 includes a substrate transfer robot positioned in a preparation space, a FOUP opener which is an opening/closing device to open and close a FOUP, an aligner positioned in the preparation space to adjust an orientation of a substrate, and a preparation space adjustment device to adjust air filled in the preparation space. Further, a substrate processing device includes a processing device body to process a substrate in a processing space, and a processing space adjustment device to adjust air filled in the processing space.

### REFERENCE DOCUMENT OF CONVENTIONAL ART

### Patent Document

### [Patent Document 1] JP2013-198981A

### DESCRIPTION OF THE DISCLOSURE

### Problem to be Solved by the Disclosure

According to Patent Document 1, the FOUP and the processing device are positioned closer to an outer surface of the preparation space. However, a degree of freedom in positioning the FOUP and the processing device, i.e., a degree of freedom in designing the entire system, is not taken into consideration.

Therefore, one purpose of the present disclosure is to provide a robot system with a higher degree of freedom in design.

### SUMMARY OF THE DISCLOSURE

In order to solve the problem, a robot system according to one aspect of the present disclosure includes a first placing part and a second placing part where a workpiece is placed, and a transfer device disposed between the first placing part and the second placing part. The transfer device includes a transfer-device interior space, a part of the periphery thereof being defined by a first wall provided to the first placing part side and a second wall provided to the second placing part side so as to oppose to the first wall, and a robot configured to transfer the workpiece between the first placing part and the second placing part. The first placing part is separated from the first wall by a first distance in a first direction connecting the first wall and the second wall. The second placing part is separated from the second wall by a second distance farther than the first distance in the first direction. The robot is disposed closer to the second wall.

According to this configuration, the second placing part is separated from the second wall by the second distance farther than the first distance in the first direction connecting the first wall and the second wall, and the robot is disposed closer to the second wall. Therefore, the robot system excelled in the degree of freedom in the design can be provided.

The robot may have a robotic arm, and a joint axis provided to a base end of the robotic arm may be disposed closer to an internal surface of the second wall.

According to this configuration, the effect of the robot system of the present disclosure can be boosted.

For example, the second placing part has a plurality of second placing parts. The second distance may be a distance from the second wall to the second placing part farthest from the second wall in the first direction among the plurality of second placing parts.

The robot may be disposed between the second placing part farthest from the second wall and the second placing part second farthest from the second wall in a second direction in which the second wall extends.

According to this configuration, the robot becomes easier to access each of the plurality of second placing parts.

The robot may be disposed so that a distance from the farthest second placing part is equal to a distance from the second-farthest second placing part.

According to this configuration, the robot becomes easier to access each of the plurality of second placing parts.

For example, the first placing part has a plurality of first placing parts. The first distance may be a distance from the first wall to the first placing part farthest from the first wall in the first direction among the plurality of first placing parts.

The plurality of first placing parts may be disposed closer to an external surface of the first wall.

According to this configuration, the robot becomes easier to access each of the plurality of first placing parts.

The workpiece may be a semiconductor wafer. The first placing part may be constituted as a part of an accommodating device configured to accommodate the semiconductor wafer. The second placing part may be constituted as a part of a processing unit configured to process the semiconductor wafer. The robot may be constituted as a semiconductor wafer transferring robot configured to transfer the semiconductor wafer between the accommodating device and the processing unit.

According to this configuration, the robot system according to the present disclosure can be applied to a semiconductor wafer manufacturing site.

### Effect of the Disclosure

According to the present disclosure, the robot system excelled in the degree of freedom in the design can be provided.

### BRIEF DESCRIPTION OF DRAWINGS

FIG. 1 is a schematic view illustrating the entire configuration of a robot system according to one embodiment of the present disclosure.

FIG. 2 is a schematic view illustrating the entire configuration of a modification of the robot system according to the embodiment of the present disclosure.

### MODE FOR CARRYING OUT THE DISCLOSURE

Hereinafter, one embodiment of the present disclosure is described based on the accompanying drawings. Note that, below, the same reference characters are assigned to the same or corresponding components throughout the drawings to omit the redundant description.

### (Robot System 10)

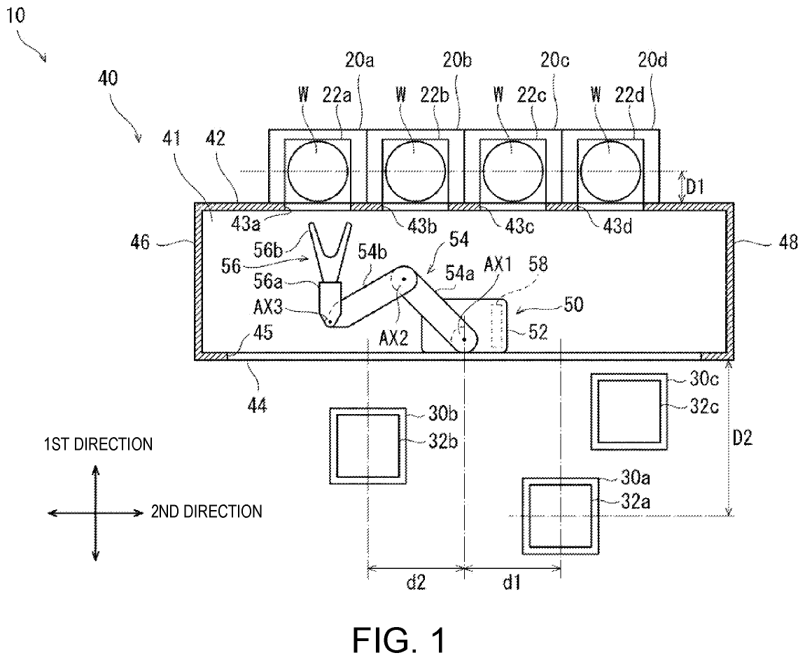

FIG. 1 is a schematic view illustrating the entire configuration of a robot system according to one embodiment of the present disclosure. As illustrated in FIG. 1, the robot system 10 according to this embodiment includes four accommodating devices 20a to 20d which accommodate semiconductor wafers W (workpiece), three processing units 30a to 30c which perform processings to the semiconductor wafers W, and a transfer device 40 disposed between the accommodating devices 20a to 20d and the processing units 30a to 30c.

### (Accommodating Device 20)

Each of the accommodating devices 20a to 20d may be constituted as a so-called FOUP (Front Opening Unified Pod) which can accommodate a plurality of semiconductor wafers W in a vertically stacked manner. That is, each of the accommodating devices 20a to 20d may have a hollow container body formed in a rectangular parallelepiped shape, and a container-side door which can open and close an opening formed in one of side surfaces of the container body, and may have a sealed structure suitable for a clean environment.

The accommodating devices 20a to 20d have first placing parts 22a to 22d where semiconductor wafers W are placed, respectively. In other words, the first placing parts 22a to 22d are constituted as parts of the accommodating devices 20a to 20d, respectively.

### (Processing Unit 30)

Processings which the processing units 30a to 30c apply to the semiconductor wafers W may be, for example, heat treatment, impurity introduction, thin film formation, lithography, rinsing, and etching. Moreover, each of the processing units 30a to 30c may be constituted as an inlet or outlet for performing one processing to the semiconductor wafer W. For example, the processing unit 30a may be constituted as an inlet for a heat treatment to the semiconductor wafer W, and the processing unit 30b may be constituted as an outlet therefor.

The processing units 30a to 30c have second placing parts 32a to 32c for placing the semiconductor wafers W, respectively. In other words, the second placing parts 32a to 32c are constituted as parts of the processing units 30a to 30c, respectively.

### (Transfer Device 40)

The transfer device 40 has a transfer-device interior space 41, and a semiconductor wafer transfer robot 50 (hereinafter, simply referred to as “the robot 50”) for transferring the semiconductor wafers W between the accommodating devices 20a to 20d and the processing units 30a to 30c, respectively.

### (Transfer-Device Interior Space 41)

The transfer-device interior space 41 has a known configuration where the air cleanliness is secured. The transfer-device interior space 41 defines a part of the periphery thereof by a first wall 42 provided on the accommodating devices 20a to 20d side, and a second wall 44 provided on the processing units 30a to 30c side so as to oppose to the first wall 42. Note that the first wall 42 and the second wall 44 extend in parallel to each other in the plan view. In the following description, a direction which connects the first wall 42 and the second wall 44 is referred to as a “first direction.” Moreover, an extending direction of the first wall 42 and the second wall 44 (i.e., a direction which connects a third wall 46 and a fourth wall 48, which will be described later) is referred to as a “second direction.”

First openings 43a to 43d through which a part of the robot 50 can pass are formed in the first wall 42. The first openings 43a to 43d are formed at positions corresponding to the accommodating devices 20a to 20d, respectively. Each of the first openings 43a to 43d may be openable and closable by being provided with a first room-side door (not illustrated). Therefore, the air cleanliness inside the transfer-device interior space 41 may be secured.

A second opening 45 through which a part of the robot 50 can pass is formed in the second wall 44. The second opening 45 is formed from near one of edges (the left edge in FIG. 1) of the second wall 44 in the second direction to near the other edge (the right edge in FIG. 1) in the same direction. The second opening 45 may be openable and closable by being provided with a second room-side door (not illustrated). Therefore, the air cleanliness inside the transfer-device interior space 41 may be secured.

The transfer-device interior space 41 further defines the part of the periphery thereof by the third wall 46 extending in the first direction so that one of edges (the left edge in FIG. 1) of the first wall 42 in the second direction is connected to one of edges (same as above) of the second wall 44 in the second direction, and the fourth wall 48 extending in the first direction so that the other edge (the right edge in FIG. 1) of the first wall 42 in the second direction is connected to the other edge (same as above) of the second wall 44 in the second direction.

### (Robot 50)

The robot 50 according to this embodiment is a so-called horizontal articulated 3-axis robot, which has three joint axes (a joint axis AX1, a joint axis AX2, and a joint axis AX3). The robot 50 includes a pedestal 52 and an elevatable shaft (not illustrated) which is provided to an upper surface of the pedestal 52 and is expandable and contractible in the up-and-down direction.

The robot 50 also includes a robotic arm 54 attached to an upper end part of the elevatable shaft, a hand 56 (end effector) attached to a tip-end part of the robotic arm 54, and a robot controller 58 which controls the hand 56 and the robotic arm 54.

The elevatable shaft provided to the upper surface of the pedestal 52 is expandable and contractible by an air cylinder (not illustrated). The robotic arm 54 includes a first link 54a and a second link 54b which are each comprised of an elongated member extending horizontally.

The first link 54a is attached to an upper end part of the elevatable shaft through the joint axis AX1 (a joint axis provided to a base end of the robotic arm) of which one of end parts in the longitudinal direction is driven by a servomotor (not illustrated). Thus, the first link 54a is attached to the elevatable shaft rotatably about an axis extending in the vertical direction.

The second link 54b is attached to the other end part of the first link 54a through the joint axis AX2 of which one of end parts in the longitudinal direction is driven by a servomotor (not illustrated). Thus, the second link 54b is attached to the first link 54a rotatably about an axis extending in the vertical direction.

The hand 56 is attached to the other end part of the second link 54b through the joint axis AX3 of which one of end parts in the longitudinal direction is driven by a servomotor (not illustrated). Thus, the hand 56 is attached to the second link 54b rotatably about an axis extending in the vertical direction.

The hand 56 has a base part 56a including the joint axis AX3, and a hold part 56b attached to a tip-end part of the base part 56a. The hold part 56b is branched in a two-fork shape at a tip-end side thereof, and is formed in a Y-shape in the plan view.

### (Robot Controller 58)

Although the concrete configuration of the robot controller 58 is not limited in particular, it may be implemented, for example, by a known processor (e.g., a CPU) operating according to a program stored in a storage part (memory).

### (Arrangement of Each Component)

Here, an arrangement of each component described above is described in detail. The accommodating devices 20a to 20d are disposed closer to an external surface of the first wall 42 of the transfer-device interior space 41, and are lined up side-by-side so as to be adjacent to each other. That is, the first placing parts 22a to 22d are separated from the first wall 42 by the same first distance D1 in the first direction.

Here, the first distance D1 is a distance between the external surface of the first wall 42 and the center of the semiconductor wafer W formed in a disc shape in the plan view. Note that, since the accommodating devices 20a to 20d are each disposed closer to the external surface of the first wall 42, a distance between end parts of the semiconductor wafers W on the first wall 42 side, which are placed on the first placing parts 22a to 22b and the external surface of the first wall 42 is 0 or substantially 0.

The processing units 30a to 30b are separated from the second wall 44 in the first direction by different distances. The processing unit 30a is disposed most distant from the second wall 44, the processing unit 30b is disposed the second distant from the second wall 44, and the processing unit 30c is disposed closest to the second wall 44.

Here, the second distance D2 from the second wall 44 to the second placing parts 32a to 32c corresponding to the first distance D1 from the first wall 42 to the first placing parts 22a to 22d is the distance in the first direction from the second wall 44 to the farthest second placing part 32a among the second placing parts 32a to 32c. As illustrated, the second distance D2 is larger than the first distance D1. That is, the second placing part 32a is separated from the second wall 44 by the second distance D2 which is farther than the first distance D1.

The robot 50 is disposed closer to an internal surface of the second wall 44. In detail, in this embodiment, the pedestal 52 of the robot 50 and the joint axis AX1 disposed at an end part of the upper surface of the pedestal 52 on the second wall 44 side in the first direction are closer to the internal surface of the second wall 44.

Moreover, the robot 50 is disposed in the second direction between the second placing part 32a which is farthest from the second wall 44 and the second placing part 32b which is the second farthest from the second wall 44. In this embodiment, particularly, the robot 50 is disposed in the middle of the farthest second placing part 32a and the second-farthest second placing part 32b. That is, the illustrated distances d1 and d2 are equal to each other.

In detail, in this embodiment, the pedestal 52 of the robot 50 and the joint axis AX1 disposed at the end part of the upper surface of the pedestal 52 on the second wall 44 side in the first direction are disposed in the middle of the second placing part 32a farthest from the second wall 44 and the second placing part 32b second farthest from the second wall 44.

### (Example and Effects of Treatment Process to Semiconductor Wafer W)

Here, one example of a heat treatment process performed to the semiconductor wafer W by using the robot system 10 according to the above embodiment is described. In addition, effects obtained by the robot system 10 according to the above embodiment is described.

First, the robotic arm 54 is made in such a posture that it can hold the semiconductor wafer W placed on the first placing part 22a of the accommodating device 20a from the initial state. Note that the robot 50 can be made into the above posture by the hand 56 passing through the first opening 43a formed in the first wall 42.

Next, the hold part 56b of the hand 56 holds the semiconductor wafer W placed on the first placing part 22a.

Further, the robotic arm 54 is made into such a posture that it can place the semiconductor wafer W held by the hold part 56b onto the second placing part 32a of the processing unit 30a.

Here, since the robot 50 is disposed closer to the internal surface of the second wall 44, it can easily reach the second placing part 32a disposed comparatively distant from the second wall 44. Moreover, since the second placing part 32a is disposed comparatively distant from the second wall 44, it is possible to provide other second placing parts 32a between the second wall 44 and this second placing part 32a in various layouts, for example. Further, when achieving the posture where the robot 50 can place the semiconductor wafer W held by the hold part 56b onto the second placing part 32a of the processing unit 30a, it can reach the second placing part 32a while appropriately avoiding the processing units 30b and 30c which may become obstacles.

As described above, it is possible to provide the robot system 10 excellent in a degree of freedom in arrangement of the second placing parts 32, i.e., the robot system 10 excellent in a degree of freedom in design.

Then, the semiconductor wafer W held by the hold part 56b is placed on the second placing part 32a.

Next, a heat treatment is applied to the semiconductor wafer W. The heat-treated semiconductor wafer W is placed on the second placing part 32b of the processing unit 30b. That is, here, the processing unit 30a is constituted as an inlet for the heat treatment to the semiconductor wafer W, and the processing unit 30b is constituted as the outlet.

Further, the robotic arm 54 is made into a posture where it can hold the processed semiconductor wafer W placed on the second placing part 32b.

Here, since the robot 50 is disposed in the middle of the second placing part 32a farthest from the second wall 44 and the second placing part 32b second farthest from the second wall 44 in the second direction, the robot 50 becomes easier to access the second placing parts 32a to 32c.

Note that the robot 50 becomes more difficult to reach the second placing parts 32 as the second placing parts 32 are disposed farther from the second wall 44. Therefore, the robot 50 becomes easier to access all the second placing parts 32a to 32c by disposing the robot 50 as described above.

Then, the processed semiconductor wafer W placed on the second placing part 32b is held by the hold part 56b.

Next, the robotic arm 54 is made into a posture where it can place the processed semiconductor wafer W held by the hold part 56b onto the first placing part 22b of the accommodating device 20b.

Further, the processed semiconductor wafer W held by the hold part 56b is placed on the first placing part 22b.

As described above, the semiconductor wafer W can be heat-treated using the robot system 10 according to the above embodiment. Note that, similarly, the robot system 10 can perform impurity introduction, thin film formation, lithography, rinsing, flattening, etc. to the semiconductor wafer W placed on any of the accommodating devices 20a to 20d at any of the processing units 30a to 30c.

### (Modification)

It is apparent for the person skilled in the art that many improvements and other embodiments of the present disclosure are possible from the above description. Therefore, the above description is to be interpreted only as illustration, and it is provided in order to teach the person skilled in the art the best mode that implements the present disclosure. The details of the configurations and/or the functions may be changed substantially without departing from the sprit of the present disclosure.

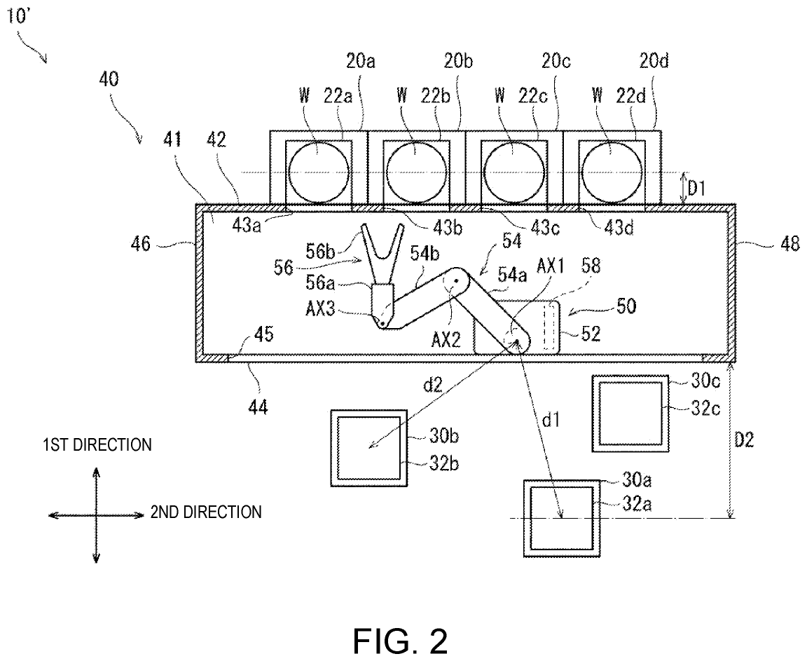

FIG. 2 is a schematic view illustrating the entire configuration of a modification of the robot system according to the above embodiment of the present disclosure. Note that the robot system 10′ according to this modification has the same configuration as the robot system 10 according to the above embodiment, except for the arrangement of the robot 50. Therefore, the same reference characters are given to the same part, and similar description is not repeated.

As illustrated in FIG. 2, in this modification, the robot 50 is disposed closer to the second wall 44, and is disposed so that the distance d1 from the farthest second placing part 32a is equal to the distance d2 from the second-farthest second placing part 32b. Even when the robot 50 is disposed in this manner, it is possible to provide the robot system 10′ excelled in the degree of freedom in the arrangement of the second placing parts 32, i.e., the robot system 10′ excelled in the degree of freedom in the design, similar to the above embodiment.

Although in the above embodiment and its modification, the pedestal 52 and the joint axis AX1 of the robot 50 are disposed closer to the internal surface of the second wall 44, the present disclosure is not limited to this case, as long as the robot 50 is disposed closer to the second wall 44. In detail, for example, only the joint axis AX1 (the joint axis provided to the base end of the robotic arm) may be disposed closer to the internal surface of the second wall 44, and a part of the pedestal 52 may be disposed outside the transfer-device interior space 41 from the second wall 44.

Although in the above embodiment and its modification, the four first placing parts 22 (and the four accommodating devices 20) are disposed closer to the external surface of the first wall 42 and are lined up side-by-side, the present disclosure is not limited to this configuration. That is, the number of the first placing parts 22 may be one or more and three or less, or may be five or more.

Note that, when a plurality of first placing parts 22 are provided, the plurality of first placing parts 22 may be separated from the first wall 42 in the first direction by different distances. Here, the first distance D1 is a distance in the first direction from the first wall 42 to the first placing part 22 farthest from the first wall 42 among the plurality of first placing parts 22.

Although in the above embodiment and its modification, the second opening 45 is formed from near the one edge of the second wall 44 in the second direction to near the other edge in the same direction, the present disclosure is not limited to this configuration. For example, the second openings 45 may be formed at positions of the second wall 44 corresponding to the processing units 30a to 30c in the second direction. Moreover, two, or four or more second openings 45 may be formed in the second wall 44. Here, the plurality of second openings 45 may be openable and closable by being provided with the second room-side doors.

Although in the above embodiment and its modification, the three second placing parts 32 (and the three processing units 30) are separated from the second wall 44 by different distances, the present disclosure is not limited to this configuration. That is, the number of second placing parts 32 may be one or two, or may be four or more.

Note that, when the plurality of second placing parts 32 are provided, the plurality of second placing parts 32 may be separated from the second wall 44 by the same distance in the first direction. Alternatively, only some of the second placing parts 32 among the plurality of second placing parts 32 may be separated from the second wall 44 by the same distance, and the remaining second placing parts 32 may be separated from the second wall 44 by different distances. Here, the second placing part 32 farthest from the second wall 44 and the second placing part 32 second farthest from the second wall 44 may be separated form the second wall 44 by the same distance in the second direction.

Moreover, when the plurality of second placing parts 32 are provided, the plurality of second placing parts 32 may be provided at different heights. Therefore, it is possible to further improve the degree of freedom in the design of the second placing parts 32. Note that, since the same can be said for the plurality of first placing parts 22, the description is not repeated herein.

Although in the above embodiment and its modification, the robot 50 is disposed in the middle of the second placing part 32a farthest from the second wall 44 and the second placing part 32b second farthest from the second wall 44 in the second direction, it is not limited to this configuration.

For example, the robot 50 may be disposed at a location other than the middle (center) of the second placing part 32a farthest from the second wall 44 and the second placing part 32b second farthest from the second wall 44 in the second direction. Moreover, for example, the robot 50 may be disposed at the same position as the processing unit 30 farthest from the second wall 44 in the second direction, or may be disposed at other locations as long as it is disposed closer to the internal surface of the second wall 44.

Although in the above embodiment and its modification, the robotic arm 54 has the two links 54a and 54b, it is not limited to this configuration. For example, the robotic arm 54 may have three links. Alternatively, the robotic arm 54 may have one link, or four or more links.

Note that, by increasing the number of links of the robotic arm 54, for example, when making the semiconductor wafer W held by the hold part 56b of the hand 56 into the posture where it can be placed on the second placing part 32 of the processing unit 30, it becomes easier for the robotic arm 54 to be reachable while appropriately avoiding the processing unit 30 which may become an obstacle.

Moreover, if the servomotor provided to one end part of the first link 54a, the servomotor provided to one end part of the second link 54b, and the servomotor provided to one end part of the hand 56 are independently rotatable, it becomes possible to boost the effects described above.

Although in the above embodiment and its modification, the first placing part 22 is constituted as a part of the accommodating device 20 and the second placing part 32 is constituted as a part of the processing unit 30, the present disclosure is not limited to this configuration. For example, the first placing part may be constituted as a part of the processing unit and the second placing part may be constituted as a part of the accommodating device.

Although in the above embodiment and its modification, the robot system 10 is applied to the semiconductor wafer manufacturing site, it may be applied to other sites requiring the transfer of the workpiece between the first placing part and the second placing part, without being limited to the semiconductor wafer manufacturing site. In such a case, the first placing part and the second placing part may be constituted as parts of devices other than the accommodating device and the processing unit.

Further, for example, the robot 50 may be disposed closer to the wall (the first wall 42 or the second wall 44) with more number of placing parts (the first placing part 22 or the second placing part 32) lined up in the first direction. Here, the number of placing parts disposed at the same location in the first direction is excluded. Thus, by disposing the robot 50 closer to the wall with various distances from the placing parts, it is possible to increase the degree of freedom in the design of the robot system 10.

### DESCRIPTION OF REFERENCE CHARACTERS

10 Robot System
20 Accommodating Device
22 First Placing Part
30 Processing Unit
32 Second Placing Part
40 Transfer Device
41 Transfer-device Interior Space
42 First Wall
43 First Opening
44 Second Wall
45 Second Opening
50 Robot
52 Pedestal
54 Robotic Arm
56 Hand
58 Robot Controller
AX Joint Axis
W Semiconductor Wafer

1. A robot system, comprising:
a first placing part and a second placing part where a workpiece is placed; and
a transfer device disposed between the first placing part and the second placing part, the transfer device including:
a transfer-device interior space, a part of the periphery thereof being defined by a first wall provided to the first placing part side and a second wall provided to the second placing part side so as to oppose to the first wall; and
a robot configured to transfer the workpiece between the first placing part and the second placing part,
wherein the first placing part is separated from the first wall by a first distance in a first direction connecting the first wall and the second wall,
wherein the second placing part has three or more second placing parts, and among the three or more second placing parts, the second placing part farthest from the second wall is separated from the second wall by a second distance farther than the first distance in the first direction,
wherein, among the three or more second placing parts, the second distance is different from a distance from the second wall to the second placing part second farthest from the second wall in the first direction,
wherein the robot is disposed closer to the second wall, between the farthest second placing part and the second-farthest second placing part in a second direction in which the second wall extends.

2. The robot system of claim 1, wherein the robot has a robotic arm, and a joint axis provided to a base end of the robotic arm is disposed closer to an internal surface of the second wall.

3-4. (canceled)

5. The robot system of claim 1, wherein one of two second placing parts of the three or more second placing parts is the second placing part farthest from the robot, and a distance to the one of the second placing parts from the robot is equal to a distance to the other second placing part from the robot.

6. The robot system of claim 1, wherein the first placing part has a plurality of first placing parts, and
wherein the first distance is a distance from the first wall to the first placing part farthest from the first wall in the first direction among the plurality of first placing parts.

7. The robot system of claim 6, wherein the plurality of first placing parts are disposed closer to an external surface of the first wall.

8. The robot system of claim 1, wherein the workpiece is a semiconductor wafer,
wherein the first placing part is constituted as a part of an accommodating device configured to accommodate the semiconductor wafer,
wherein the three or more second placing parts are each constituted as a part of a processing unit configured to process the semiconductor wafer, and
wherein the robot is constituted as a semiconductor wafer transferring robot configured to transfer the semiconductor wafer between the accommodating device and the processing unit.
